(19) United States
(12) Patent Application Publication
(10) Pub. No.: US 2021/0348026 A1
(43) Pub. Date: Nov. 11, 2021

(54) SILICON PRECURSOR AND METHOD OF FABRICATING SILICON-CONTAINING THIN FILM USING THE SAME

(71) Applicant: HANSOL CHEMICAL CO., LTD., Seoul 06169 (KR)

(72) Inventors: Jae-Seok An, Jeollabuk-do 55316 (KR); Yeong-Eun Kim, Jeollabuk-do 54835 (KR); Jang-Hyun Seok, Sejong-si 30062 (KR); Jung-Woo Park, Seoul 05503 (KR)

(21) Appl. No.: 17/314,784

(22) Filed: May 7, 2021

(30) Foreign Application Priority Data
May 8, 2020 (KR) 10-2020-0054948

(51) Int. Cl. C09D 183/16; C23C 16/455; C23C 16/50

(52) U.S. Cl. CPC C09D 183/16; C23C 16/50; C23C 16/45553

(57) ABSTRACT

The present disclosure relates to a vapor deposition compound which may be deposited as a thin film by vapor deposition, and specifically, to a silicon precursor which is applicable to atomic layer deposition (ALD) or chemical vapor deposition (CVD) and may be deposited at high rate, particularly by high-temperature ALD, and a method for fabricating a silicon-containing thin film using the same.

### CROSS-REFERENCE TO RELATED APPLICATION

This application claims priority from and the benefit of Korean Patent Application No. 10-2020-0054948, filed on May 8, 2020, which is hereby incorporated by reference for all purposes as if set forth herein.

### BACKGROUND

### Field

The present disclosure relates to a vapor deposition compound which may be deposited as a thin film by vapor deposition, and more particularly, to a novel silicon precursor which is applicable to atomic layer deposition (ALD) or chemical vapor deposition (CVD) and may be used for the fabrication of a thin film having excellent quality, particularly at a high process temperature, and a method for fabricating a silicon-containing thin film using the same.

### Discussion of the Background

Silicon-containing thin films are used as semiconductor substrates, diffusion masks, oxidation barriers and dielectric films in semiconductor technologies such as microelectronic devices including RAMs (memory and logic chips), flat panel displays such as thin film transistors (TFTs), and solar heat applications.

In particular, with the increasing integration density of semiconductor devices, silicon-containing thin films having various performances have been required and the aspect ratio thereof has increased. Thus, a problem arises in that deposition of silicon-containing thin films using conventional precursors does not meet the required performance.

When a thin film is deposited on a highly integrated semiconductor device using a conventional precursor, a problem arises in that it is difficult to achieve excellent step coverage of the thin film and control the thickness thereof, and impurities are contained in the thin film.

Thus, for deposition of high-quality silicon-containing thin films, various silicon precursors such as aminosilanes, in addition to conventional silicon precursors such as silanes, disalines and halogenated silanes, have been studied and developed.

Aminosilane precursors that are widely used generally include butyl aminosilane (BAS), bis(tertiary butylamino)silane (BTBAS), dimethyl aminosilane (DMAS), bis(tertiary methylamino)silane (BDMAS), tris(dimethylamino)silane (3-DMAS), diethyl aminosilane (DEAS), bis(diethylamino)silane (BDEAS), dipropyl aminosilane (DPAS), and diisopropyl aminosilane (DIPAS).

For fabrication of silicon-containing thin films, atomic layer deposition (ALD) or chemical vapor deposition (CVD) is widely used.

Particularly, the use of ALD to form a silicon-containing thin film has an advantage in that the thickness uniformity and physical properties of the thin film may be improved, leading to improvement in the characteristics of a semiconductor device. Due to this advantage, the use of ALD recently increased greatly. However, since CVD and ALD have different reaction mechanisms, a precursor suitable for application to CVD, when applied to ALD, may not be fabricated into a thin film having desired quality. For this reason, precursors applicable to both CVD and ALD have been increasingly studied and developed.

Meanwhile, patents related to the use of precursors such as tris(dimethylamino)silane (3-DMAS), which is one of the aminosilane precursors, include U.S. Pat. No. 5,593,741. However, even when 3-DMAS was used as a precursor, it was still impossible to obtain a high-quality thin film at a high process temperature. In addition, even when a silicon precursor substituted with a halogen element was used, it was effective in low-temperature deposition, but it was still impossible to obtain a high-quality thin film at a high process temperature.

### PRIOR ART DOCUMENTS

### Patent Documents

(Patent Document 1) Korean Patent Application Publication No. 2011-0017404

(Patent Document 2) U.S. Pat. No. 5,593,741

### SUMMARY

The present disclosure is intended to provide a novel silicon compound applicable to either of atomic layer deposition (ALD) or chemical vapor deposition (CVD).

In particular, an object of the present disclosure is to provide a silicon precursor including a novel silicon compound which may ensure the behavior of ALD at high temperature due to its possible application at a high process temperature of 600° C. or higher, may form a silicon oxide film having a low impurity concentration (particularly impurities such as Cl, C and N are not detected), may ensure excellent step coverage characteristics and surface characteristics (roughness, etc.), and thus has excellent interfacial characteristics while having excellent corrosion resistance, and a method for fabricating a silicon-containing thin film using the same.

However, objects of the present disclosure are not limited to the above-mentioned object, and other objects that are not mentioned herein will be clearly understood by those skilled in the art from the following description.

One aspect of the present disclosure provides a method for fabricating a thin film, the method including a step of introducing a vapor deposition precursor including a compound represented by the following Formula 1 into a chamber:

SiX¹ₙ(NR¹R²)(₄₋ₙ) [Formula 1]

wherein n is an integer ranging from 1 to 3, X¹ is any one selected from the group consisting of Cl, Br and I, and R¹ and R² are each independently hydrogen, a substituted or unsubstituted, linear or branched, saturated, or unsaturated hydrocarbon group having 1 to 4 carbon atoms, or an isomer thereof.

Another aspect of the present disclosure provides the method for fabricating a thin film, wherein R¹ and R² each independently comprise any one selected from the group consisting of hydrogen, a methyl group, an ethyl group, an n-propyl group, an isopropyl group, an n-butyl group, an isobutyl group, a sec-butyl group, a tert-butyl group, and isomers thereof.

Still another aspect of the present disclosure provides the method for fabricating a thin film, wherein, in Formula 1, n is 3, and R¹ and R² are each independently an isopropyl group.

Yet another aspect of the present disclosure provides the method for fabricating a thin film, wherein the method is performed by a method selected from among atomic layer deposition (ALD) and chemical vapor deposition (CVD).

Still yet another aspect of the present disclosure provides the method for fabricating a thin film, wherein the method further includes a step of injecting any one or more reactant gases selected from the group consisting of oxygen (O₂), water (H₂O), ozone (O₃), a mixture of oxygen (O₂) and hydrogen (H₂), nitrogen (N₂), ammonia (NH₃), nitrous oxide (N₂O), and hydrogen peroxide (H₂O₂).

A further aspect of the present disclosure provides the method for fabricating a thin film, wherein the method further includes a step of performing deposition at a process temperature of 600° C. or higher.

Another further aspect of the present disclosure provides a thin film which is fabricated by the fabrication method according to the present disclosure and has a surface roughness of 0.2 nm or less and a density of 2.5 g/cm³ or more.

Still another further aspect of the present disclosure provides an electronic device including the thin film fabricated according to the present disclosure, the electronic device being any one selected from the group consisting of a semiconductor device, a display device, and a solar cell.

### BRIEF DESCRIPTION OF THE DRAWINGS

FIG. 1 shows the results of nuclear magnetic resonance (NMR) analysis of a precursor of Example 1.

FIG. 2 is a graph showing the deposition rate (Å/cycle) as a function of the injection time of the precursor of Example 1 when the deposition was performed using the precursor of Example 1 at a process temperature of each of 600° C., 700° C. and 750° C. (Fabrication Examples 1 to 3).

FIG. 3 depicts graphs showing the results of X-ray photoelectron spectroscopy (XPS) performed to measure the compositions of silicon oxide films fabricated by depositing the precursor of Example 1 at process temperatures of 600° C. (FIG. 3a) and 750° C. (FIG. 3b), respectively (Experimental Example 1).

FIG. 4 depicts atomic force microscopy (AFM) and scanning electron microscopy (SEM) images of silicon oxide films fabricated by depositing the precursor of Example 1 at process temperatures of 600° C. (FIG. 4a) and 750° C. (FIG. 4b), respectively, and shows the results of analyzing the surface states (including surface roughness (Ra)) of the silicon oxide films by SEM (Experimental Example 2).

FIG. 5 shows the results of X-Ray Reflectometry (XRR) of silicon oxide films fabricated by depositing the precursor of Example 1 at process temperatures of 600° C. (FIG. 5a) and 750° C. (FIG. 5b), respectively, and shows the density values of the silicon oxide films, measured by XRR (Experimental Example 3).

FIG. 6 shows the results of scanning electron microscopy (SEM) performed to measure the thicknesses before etching (FIG. 6a) and after etching (FIG. 6b) of a silicon oxide film fabricated by depositing the precursor of Example 1 (Experimental Example 4).

### DETAILED DESCRIPTION OF THE ILLUSTRATED EMBODIMENTS

Hereinafter, embodiments and examples of the present disclosure will be described in detail with reference to the accompanying drawings so that those skilled in the art may easily carry out the present disclosure. However, the present disclosure may be embodied in a variety of different forms and is not limited to the embodiments and examples described herein and the accompanying drawings. In the drawings, parts not related to the description are omitted in order to clearly describe the present disclosure.

One aspect of the present disclosure provides a method for fabricating a thin film, the method including a step of introducing a vapor deposition precursor including a compound represented by the following Formula 1 into a chamber:

SiX¹ₙ(NR¹R²)₍₄₋ₙ₎ [Formula 1]

wherein n is an integer ranging from 1 to 3, X¹ is any one selected from the group consisting of Cl, Br and I, and R¹ and R² are each independently hydrogen, a substituted or unsubstituted, linear or branched, saturated, or unsaturated hydrocarbon group having 1 to 4 carbon atoms, or an isomer thereof.

Preferably, R¹ and R² may be each independently any one selected from the group consisting of hydrogen, a methyl group, an ethyl group, an n-propyl group, an isopropyl group, an n-butyl group, an isobutyl group, a sec-butyl group, a tert-butyl group, and isomers thereof.

More preferably, in Formula 1, n may be 3 without being limited thereto, and R¹ and R² may be each independently an isopropyl group, without being limited thereto.

The step of introducing the vapor deposition precursor into the chamber may include, but is not limited to, a physical adsorption step, a chemical adsorption step, and a physical and chemical adsorption step.

In one embodiment of the present disclosure, the vapor deposition may include, but is not limited to, atomic layer deposition (ALD) or chemical vapor deposition (CVD), and the chemical vapor deposition may include, but is not limited to, metal organic chemical vapor deposition (MOCVD), or low-pressure chemical vapor deposition (LPCVD).

In one embodiment of the present disclosure, the method for fabricating a thin film may further include a step of injecting any one or more reactant gases selected from the group consisting of oxygen (O₂), water (H₂O), ozone (O₃), a mixture of oxygen (O₂) and hydrogen (H₂), nitrogen (N₂), ammonia (NH₃), nitrous oxide (N₂O), and hydrogen peroxide (H₂O₂).

In addition, various oxygen-containing reactants, nitrogen-containing reactants or carbon-containing reactants may also be used depending on the required characteristics of the thin film, but the scope of the present disclosure is not limited thereto.

In one embodiment of the present disclosure, the method for fabricating a thin film may be performed at a high temperature. The precursor may be deposited at a process temperature of 300° C. to 800° C., preferably 600° C. to 800° C.

When conventional silicon precursors are used at a high process temperature of 600° C. or higher, it is difficult to control film thicknesses, and high-quality thin films having desired characteristics are not provided. However, the novel silicon precursor of the present disclosure is thermally stable even at 600° C. or higher, and thus may provide a thin film having excellent quality even in a high-temperature process.

Another aspect of the present disclosure provides a high-purity amorphous silicon oxide film which is fabricated by the method for fabricating a thin film and has a surface roughness of 0.2 nm or less and a density of 2.5 g/cm³ or more, preferably 2.55 g/cm³ or more. The thin film may be provided as various thin films such as oxide, nitride, carbide, carbonitride and oxynitride films, depending on the choice of the reactant. In addition, the thin film is expected to have excellent interfacial characteristics and corrosion resistance due to the surface characteristics and density thereof.

Still another aspect of the present disclosure provides a multilayered thin film including the thin film fabricated according to the present disclosure.

Yet another aspect of the present disclosure provides an electronic device including the thin film fabricated according to the present disclosure. The electronic device may be any one selected from the group consisting of a semiconductor device, a display device and a solar cell. In particular, the thin film may exhibit excellent characteristics as a tunneling oxide film for a 3D-NAND memory device.

Hereinafter, the present disclosure will be described in more detail with reference to examples, but the scope of the present disclosure is not limited to these examples.

### EXAMPLE 1

### Production of Diisopropylaminotrichlorosilane (C₆H₁₄Cl₃NSi)

SiCl₄ (1.0 eq.) was placed in a flask, diluted in pentane (12 eq.), and then cooled in a water bath maintained at 0° C. While the resulting solution was stirred, diisopropylamine (2.87 eq.) diluted in pentane (6 eq.) was added slowly to the solution. After completion of the addition, the mixture was stirred at room temperature for 15 hours. After completion of the reaction, the reaction mixture was filtered, and the filtrate solution was boiled at atmospheric pressure to remove the solvent. The obtained liquid was purified under reduced pressure to obtain a colorless transparent liquid.

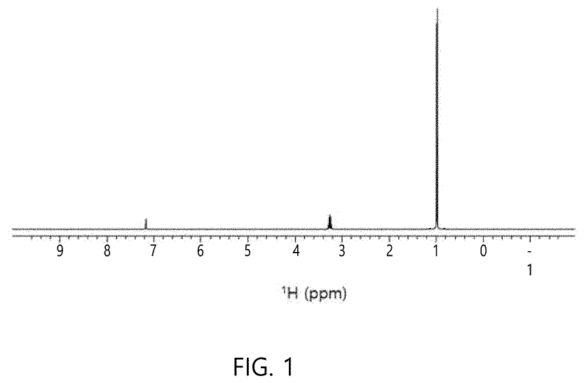

A reaction scheme for synthesis of diisopropylaminotrichlorosilane and the chemical structure of diisopropylaminotrichlorosilane are shown in the following Reaction Scheme and Chemical Structural Formula, and the chemical structure of diisopropylaminotrichlorosilane was verified by ¹H-NMR as shown in FIG. 1.

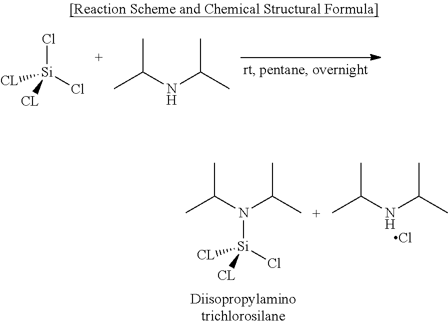

In addition, the obtained compound had a molecular weight of 234.63 g/mol, was in a colorless liquid state at room temperature, and had a boiling point of 205° C. The compound could be easily introduced into a process chamber by high vapor pressure and could provide a sufficient amount of a precursor within a short time.

[Fabrication Examples 1 to 3]

The compound produced in Example 1 above was deposited using an atomic layer deposition (ALD) system, thus fabricating a silicon oxide film. The substrate used in this experiment was a bare Si wafer. Before deposition, the bare Si wafer was ultrasonically treated sequentially in acetone, ethanol and DI water for 10 minutes each, and then the native oxide on the bare Si wafer was removed by immersion in a 10% HF solution (HF:H₂O=1:9) for 10 seconds.

Specifically, atomic layer deposition was performed for a plurality of cycles, each consisting of the following sequential steps: injection of the silicon precursor of Example 1 for X seconds; purge of the precursor with Ar for 10 seconds; injection of a reactant gas for 5 seconds; and purge of the reactant gas with Ar for 10 seconds.

In the step of injecting the silicon precursor of Example 1 for X seconds, X was set to 1 to 12 seconds, the carrier gas argon (Ar) for the precursor was injected at a flow rate of 200 sccm, and deposition of the precursor was performed at a process temperature ranging from 600° C. to 850° C.

All the canisters were heated to a temperature of 40° C., Ar for purge was injected at a flow rate of 2,000 sccm.

In addition, a mixture of hydrogen (H₂) gas and oxygen (O₂) gas (H₂+O₂) was used as the reactant gas. Silicon oxide thin films were fabricated at process temperatures of 600° C. (Fabrication Examples 1-1 to 1-5), 700° C. (Fabrication Examples 2-1 to 2-5) and 750° C. (Fabrication Examples 3-1 to 3-5).

For injection of the reactant gas, oxygen (O₂) and hydrogen (H₂) were supplied into the reaction chamber at flow rates of 1,000 sccm and 325 sccm, respectively.

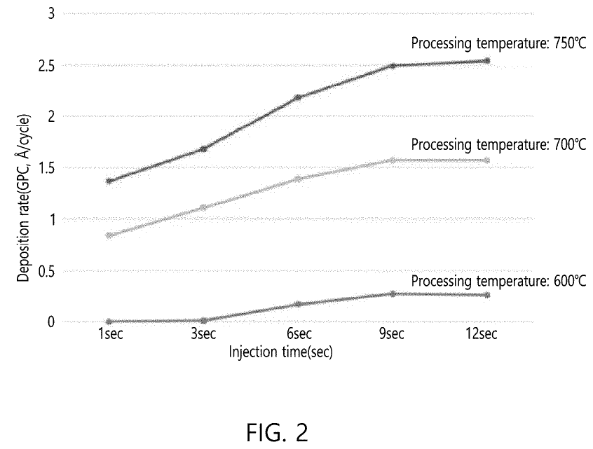

The deposition process conditions and deposition results of Fabrication Examples 1 to 3 are shown in Tables 1 to 3 below, respectively, and FIG. 2.

As shown in FIG. 2, it was observed that, even at a higher temperature of 600° C. or higher, a thin film was formed by depositing the silicon precursor compound of Example 1. Thus, it was confirmed that the silicon precursor compound of Example 1 and the silicon oxide film formed by depositing the same had excellent thermal stability even at high temperature.

In addition, from the results of the deposition experiment performed at a process temperature of 850° C., it could be confirmed that the ALD process could not be applied at a process temperature of 850° C. or higher due to thermal decomposition of the precursor compound of Example 1.

TABLE 1
Results of deposition using precursor compound of Example 1 and
reactant gas (H₂ + O₂) at process temperature of 600° C.

| | | | Injection | Purge | | | |
|---|---|---|---|---|---|---|---|
| | Injection | Purge | time (sec) | time | | | |
| | time (sec) | time (sec) | of | (sec) of | | | Deposition |
| Fabrication | of | of | reactant | reactant | Number | Thickness | rate |
| Example | precursor | precursor | gas | gas | of cycles | (Å) | (Å/cycle) |
| 1-1 | 1 | 10 | 5 | 10 | 100 | 0.7 | 0 |
| 1-2 | 3 | 10 | 5 | 10 | 100 | 1.05 | 0 |
| 1-3 | 6 | 10 | 5 | 10 | 100 | 17.4 | 0.17 |
| 1-4 | 9 | 10 | 5 | 10 | 100 | 28 | 0.28 |
| 1-5 | 12 | 10 | 5 | 10 | 100 | 26.8 | 0.27 |

Table 1 above shows the results of deposition performed at a process temperature of 600° C. It was confirmed that, as the injection time of the precursor increased from 1 second to 12 seconds, the deposition rate increased gradually, and a self-limited reaction was observed around 9 seconds.

TABLE 2
Results of deposition using precursor compound of Example 1 and
reactant gas (H₂ + O₂) at process temperature of 700° C.

| | | | Injection | Purge | | | |
|---|---|---|---|---|---|---|---|
| | Injection | Purge | time (sec) | time | | | |
| | time (sec) | time (sec) | of | (sec) of | | | Deposition |
| Fabrication | of | of | reactant | reactant | Number | Thickness | rate |
| Example | precursor | precursor | gas | gas | of cycles | (Å) | (Å/cycle) |
| 2-1 | 1 | 10 | 5 | 10 | 100 | 84 | 0.84 |
| 2-2 | 3 | 10 | 5 | 10 | 100 | 111 | 1.11 |
| 2-3 | 6 | 10 | 5 | 10 | 100 | 138 | 1.38 |
| 2-4 | 9 | 10 | 5 | 10 | 100 | 157 | 1.57 |
| 2-5 | 12 | 10 | 5 | 10 | 100 | 157 | 1.57 |

Table 2 above shows the results of deposition performed at a process temperature of 700° C. It was confirmed that, as the injection time of the precursor increased from 1 second to 12 seconds, the deposition rate increased from 0.84 to 1.57 Å/cycle, and a self-limited reaction was observed around 9 seconds.

TABLE 3
Results of deposition using precursor compound of Example 1 and
reactant gas (H₂ + O₂) at process temperature of 750° C.

| | | | Injection | Purge | | | |
|---|---|---|---|---|---|---|---|
| | Injection | Purge | time (sec) | time | | | |
| | time (sec) | time (sec) | of | (sec) of | | | Deposition |
| Fabrication | of | of | reactant | reactant | Number | Thickness | rate |
| Example | precursor | precursor | gas | gas | of cycles | (Å) | (Å/cycle) |
| 3-1 | 1 | 10 | 5 | 10 | 100 | 137 | 1.37 |
| 3-2 | 3 | 10 | 5 | 10 | 100 | 168 | 1.68 |
| 3-3 | 6 | 10 | 5 | 10 | 100 | 218 | 2.18 |
| 3-4 | 9 | 10 | 5 | 10 | 100 | 249 | 2.49 |
| 3-5 | 12 | 10 | 5 | 10 | 100 | 254 | 2.54 |

Table 3 above shows the results of deposition performed at a process temperature of 750° C. It was confirmed that, as the injection time of the precursor increased from 1 second to 12 seconds, the deposition rate increased from 1.37 to 2.54 Å/cycle, and a self-limited reaction was observed around 9 seconds.

From the deposition results in Tables 1 to 3 above and FIG. 2, it was confirmed that, as the injection time of the precursor increased, the deposition rate increased, and in the deposition experiments performed under the same process conditions except for the process temperature, the deposition rate increased as the process temperature increased.

[Experimental Example 1] Analysis of Composition of Silicon Oxide Film (SiO₂) Fabricated from Precursor of Example 1

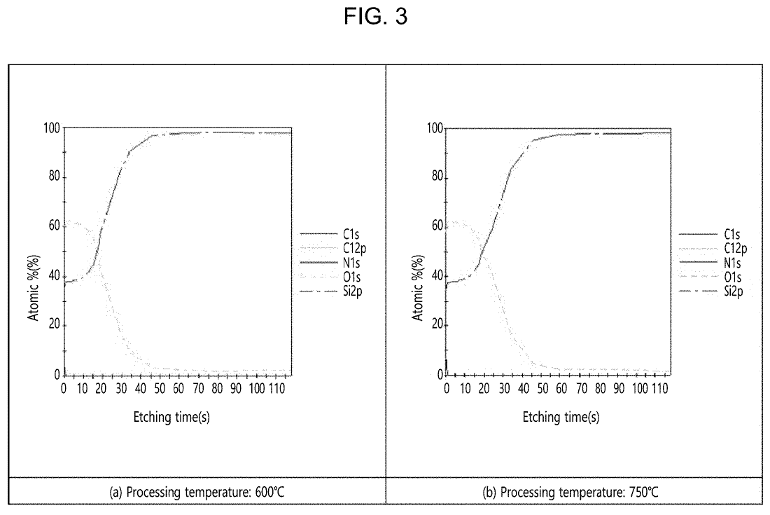

The compositions of the silicon oxide films fabricated by depositing the precursor of Example 1 and the mixture of oxygen and hydrogen (H₂+O₂) at process temperatures of 600° C. and 750° C., respectively, were analyzed by XPS analysis, and the results of the analysis are shown in FIG. 3.

As shown in FIG. 3, from the results of XPS analysis of all the thin films fabricated at process temperatures of 600° C. (FIG. 3a) and 750° C. (FIG. 3b), it could be confirmed that impurities such as carbon (C), chlorine (Cl) and nitrogen (N) were not detected, suggesting that the formed silicon thin films had excellent quality without containing impurities.

[Experimental Example 2] Surface Characteristics of Silicon Oxide Film (SiO₂) Fabricated from Precursor of Example 1

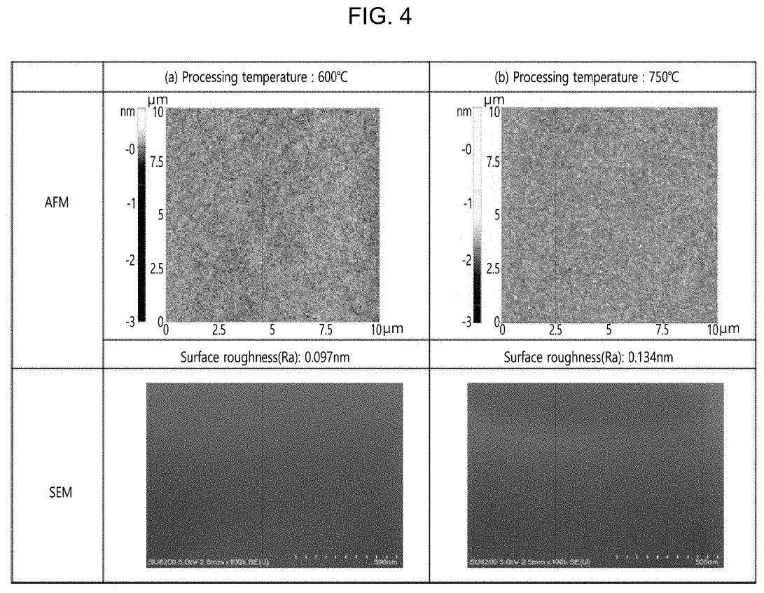

The surface roughnesses (Ra) of the silicon oxide films fabricated by depositing the precursor of Example 1 and the mixture of oxygen and hydrogen (H₂+O₂) at process temperatures of 600° C. and 750° C., respectively, were measured by observation using atomic force microscopy (AFM) and scanning electron microscopy (SEM), and the results of the measurement are shown in FIG. 4.

As shown in FIG. 4, the surface roughnesses (Ra) were measured to range from 0.097 nm to 0.134 nm, indicating that the silicon oxide films all had low roughness (1.5 Å or less). In addition, it could be confirmed that the roughness increased as the process temperature increased (FIG. 4a (process temperature: 600° C., and Ra: 0.097 nm) and FIG. 4b (process temperature: 750° C., and Ra: 0.134 nm)).

This low surface roughness could also be confirmed by SEM.

[Experimental Example 3] Density Characteristics of Silicon Oxide Film (SiO₂) Fabricated from Precursor of Example 1

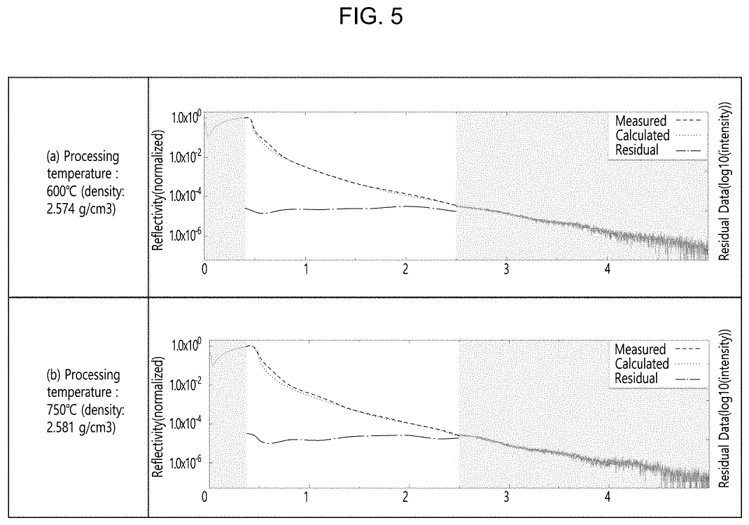

The densities of the silicon oxide films fabricated by depositing the precursor of Example 1 and the mixture of oxygen and hydrogen (H₂+O₂) at process temperatures of 600° C. and 750° C., respectively, were analyzed by XRR analysis, and the results of the analysis are shown in FIG. 5.

From the analysis results in FIG. 5, it was confirmed that, at a process temperature of 600° C., the density was 2.574 g/cm³ (FIG. 5a), and at a process temperature of 750° C., the density was 2.581 g/cm³ (FIG. 5b).

As analyzed above, it could be confirmed that the densities of the fabricated thin films were all close to that of an SiO₂ bulk thin film (2.68 g/cm³), indicating that the formed thin films had excellent quality and excellent corrosion resistance.

[Experimental Example 4] Wet Etching Characteristics of Silicon Oxide Film (SiO₂) Fabricated from Precursor of Example 1

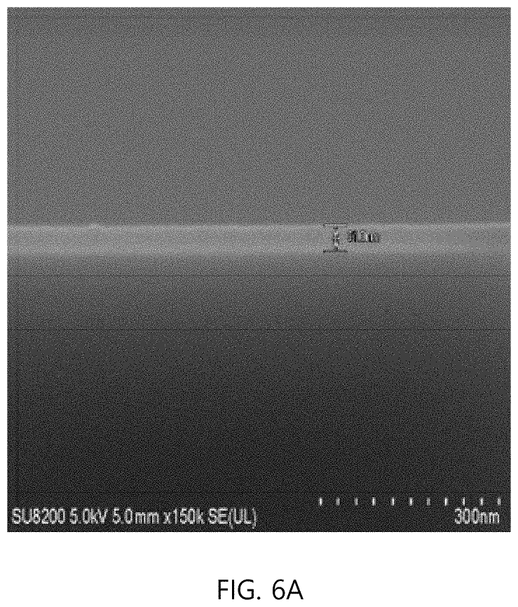

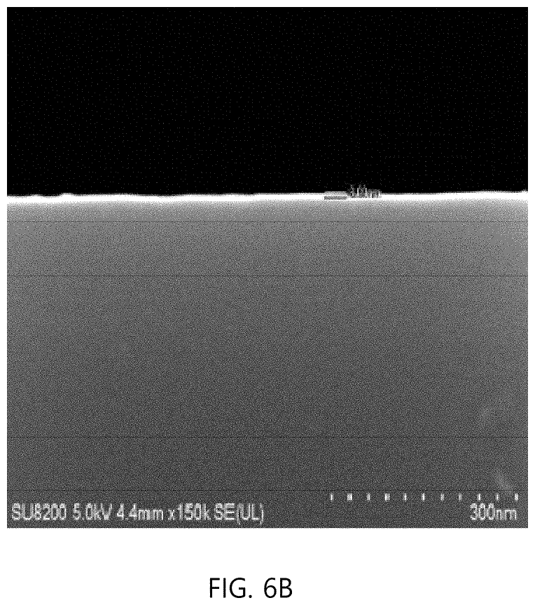

The wet etching characteristics of the silicon oxide films fabricated by depositing the precursor of Example 1 and the mixture of oxygen and hydrogen (H₂+O₂) at process temperatures of 600° C. and 750° C., respectively, were analyzed by an ellipsometer and scanning electron microscopy (SEM), and the results of the SEM analysis are shown in FIG. 6.

The thicknesses of the thin films, measured by the ellipsometer and SEM before etching (As-dep) after completion of the deposition, were 30.6 nm and 31 nm, respectively.

After the deposited thin films were etched by dipping in a solution of hydrofluoric acid (HF, diluted in distilled water at 1:200) at room temperature for 15 minutes, the thicknesses of the thin films were measured by the ellipsometer and SEM. As a result, the thicknesses were measured to be 10.3 nm and 8 nm, respectively. That is, the thickness values measured by the ellipsometer and SEM corresponded to etch rates of 1.35 and 1.53, respectively.

As described above, it was confirmed that the novel silicon precursor of the present disclosure was thermally stable even at a high process temperature of 600° C. or higher, and thus could be applied to high-temperature ALD, and the novel silicon precursor made exact thickness control possible using a low thin film growth rate and a uniform deposition rate, and had excellent density and etching characteristics. In addition, it was confirmed that a silicon thin film having excellent quality was formed by deposition of the novel silicon precursor of the present disclosure.

Due to these excellent characteristics, the high-quality silicon thin film is expected to be used as a tunneling oxide film for a 3D-NAND memory device in the future. In addition, this high-quality silicon thin film may be used in various applications, including nano-device and nano-structure fabrication, semiconductor devices, display devices, and solar cells. In addition, the high-quality silicon thin film may be used as a dielectric film or the like in the fabrication of a non-memory semiconductor device.

As described above, the novel silicon precursor according to the present disclosure has the property of not being thermally decomposed even at a high temperature of 600° C. or higher, is applicable particularly to high-temperature ALD, has a uniform deposition rate so as to make exact thickness control possible, and has excellent step coverage characteristics,

In addition, a silicon-containing thin film having excellent quality may be fabricated by deposition of the novel silicon precursor according to the present disclosure.

Due to these excellent characteristics, the high-quality silicon-containing thin film is expected to be used as a tunneling oxide film and a gap fill for a 3D-NAND memory device in the future. In addition, this high-quality silicon-containing thin film may be used in various applications, including nano-device and nano-structure fabrication, semiconductor devices, display devices, and solar cells. In addition, the high-quality-containing silicon thin film may also be used as a dielectric film for a non-memory semiconductor device.

These physical properties provide a precursor suitable for application to atomic layer deposition (ALD) and chemical vapor deposition (CVD), and this precursor is expected to be applied as a dielectric material for a semiconductor device through a process of fabricating a thin film by depositing the same.

It should be interpreted that the scope of the present disclosure is defined by the appended claims rather than the detailed description, and all altered or modified forms derived from the meaning and scope of the claims and the equivalent concepts thereof fall within the scope of the present disclosure.

1. A method for fabricating a thin film, the method comprising a step of introducing a vapor deposition precursor comprising a compound represented by the following Formula 1 into a chamber:
SiX¹ₙ(NR¹R²)₍₄₋ₙ₎ [Formula 1]
wherein
n is an integer ranging from 1 to 3,
X¹ is any one selected from the group consisting of Cl, Br and I, and
R¹ and R² are each independently hydrogen, a substituted or unsubstituted, linear or branched, saturated or unsaturated hydrocarbon group having 1 to 4 carbon atoms, or an isomer thereof.

2. The method of claim 1, wherein R¹ and R² each independently comprise any one selected from the group consisting of hydrogen, a methyl group, an ethyl group, an n-propyl group, an isopropyl group, an n-butyl group, an isobutyl group, a sec-butyl group, a tert-butyl group, and isomers thereof.

3. The method of claim 1, wherein, in Formula 1, n is 3, and R¹ and R² are each independently an isopropyl group.

4. The method of claim 1, which comprises atomic layer deposition (ALD) or chemical vapor deposition (CVD).

5. The method of claim 1, further comprising a step of injecting any one or more reactant gases selected from the group consisting of oxygen (O₂), water (H₂O), ozone (O₃), a mixture of oxygen (O₂) and hydrogen (H₂), nitrogen (N₂), ammonia (NH₃), nitrous oxide (N₂O), and hydrogen peroxide (H₂O₂).

6. The method of claim 1, further comprising a step of performing deposition at a process temperature of 600° C. or higher.

7. A thin film which is fabricated by the method of claim 1 and has a surface roughness of 0.2 nm or less and a density of 2.5 g/cm³ or more.

8. An electronic device comprising the thin film of claim 7.

9. The electronic device of claim 8, which is any one selected from the group consisting of a semiconductor device, a display device, and a solar cell.
